(19) United States
(12) Patent Application Publication
(10) Pub. No.: US 2026/0093184 A1
(43) Pub. Date: Apr. 2, 2026

(54) GREYSCALE LITHOGRAPHY FOR SUBSTRATE TOPOGRAPHY CORRECTION

(71) Applicant: Applied Materials, Inc., Santa Clara, CA (US)

(72) Inventors: Benjamin D. Briggs, Santa Clara, CA (US); Shubhendra Kumar Jain, Quincy, MA (US); Archana Kumar, Mountain View, CA (US); Ryan Ley, Santa Clara, CA (US)

(73) Assignee: Applied Materials, Inc., Santa Clara, CA (US)

(21) Appl. No.: 18/901,487

(22) Filed: Sep. 30, 2024

(51) Int. Cl. G03F 7/00; G03F 7/213

(52) U.S. Cl. CPC G03F 7/70625; G03F 7/213; G03F 7/70358; G03F 7/705; G03F 7/70655

(57) ABSTRACT

A method of substrate topography correction. The method may include receiving a thickness map of a substrate, the thickness map defining a total thickness variation across the substrate, and providing a greyscale photoresist layer on a first surface of the substrate. The method may further include performing a greyscale lithography operation on the greyscale photoresist layer, based upon the thickness map, wherein the greyscale lithography operation is to reduce the total thickness variation.

### FIELD

The present embodiments relate to stress control in substrates, and more particularly to stress compensation to manage substrate stress.

### BACKGROUND

As semiconductor devices, such as logic and memory devices, scale to smaller dimensions, efforts to improve device architecture are being made to improve performance and efficiency. One recent development is the so called backside power distribution network (BSPDN) architecture, which technology employs power circuitry that is implemented through the back surface of a semiconductor wafer, opposite to the front surface, where signal wiring is routed. This architecture employs a carrier wafer that is bonded to a device wafer, where wafer thinning may take place after bonding. The BSPDN architecture calls for uniform substrate thickness across the surface of a substrate in order to meet specified performance targets.

One issue arising from BSPDN fabrication or for any semiconductor manufacturing where uniform wafer thickness is needed is the ability to achieve the target thickness uniformity after thinning of a substrate (wafer). For example, in BPSDN fabrication, substrate thinning may take place by grinding and other mechanical processes, where the final roughness, or thickness non-uniformity, exceeds the targeted uniformity value.

With respect to these and other considerations the present embodiments are provided.

### BRIEF SUMMARY

In one embodiment a method of substrate topography correction is provided. The method may include receiving a thickness map of a substrate, the thickness map defining a total thickness variation across the substrate, and providing a greyscale photoresist layer on a first surface of the substrate. The method may further include performing a greyscale lithography operation on the greyscale photoresist layer, based upon the thickness map, wherein the greyscale lithography operation is to reduce the total thickness variation.

In a further embodiments, a lithography system is provided that includes an illumination source, to generate a scanning beam, and a controller, coupled to the scanning beam. The controller may include a processor, and a memory unit coupled to the processor, wherein the processor is operative to control the lithography system to receive a thickness map of a substrate, where the thickness map defines a total thickness variation across the substrate. The processor may be further operative to control the scanning beam to perform a greyscale lithography operation on a greyscale photoresist layer on the substrate, based upon the thickness map.

In another embodiment, a controller for a lithography system is provided. The controller may include a processor; and a memory unit coupled to the processor, wherein the processor is operative to control a lithography system to receive a thickness map of a substrate, and control a scanning beam to perform a greyscale lithography operation on a greyscale photoresist layer on the substrate, based upon the thickness map.

### BRIEF DESCRIPTION OF THE DRAWING

FIG. 1A shows an exemplary greyscale lithography system;

FIG. 1B shows further details of a controller according to some embodiments of the disclosure;

FIGS. 2A-2F depict a semiconductor device at different instances during fabrication, according to embodiments of the disclosure;

FIG. 3 is a graph depicting greyscale photoresist etch behavior as a function of dose energy when exposed to a greyscale lithography system;

FIG. 4A provides an exemplary thickness map of a semiconductor wafer;

FIG. 4B provides an exemplary dose map for a greyscale lithography system, based upon the thickness map of FIG. 4A;

FIG. 4C provides a surface image of a substrate, coated with greyscale photoresist after exposure to patterning using the exemplary dose map of FIG. 4B;

FIGS. 5A-5E provide exemplary thickness maps of a substrate, after processing using various greyscale lithography levels, according to some embodiments of the disclosure;

FIG. 6 is a graph illustrating the change in total thickness variation as a function of the number of greyscale lithography levels performed on the semiconductor substrate;

FIG. 7 illustrates an exemplary process flow;

FIG. 8 illustrates another exemplary process flow; and

FIG. 9 illustrates a further exemplary process flow.

### DETAILED DESCRIPTION

The present embodiments will now be described more fully hereinafter with reference to the accompanying drawings, where some embodiments are shown. The subject matter of the present disclosure may be embodied in many different forms and are not to be construed as limited to the embodiments set forth herein. Instead, these embodiments are provided so this disclosure will be thorough and complete, and will fully convey the scope of the subject matter to those skilled in the art. In the drawings, like numbers refer to like elements throughout.

The embodiments described herein relate to techniques and apparatus for improved substrate topography correction, including reducing the total thickness variation (TTV) of a semiconductor wafer. As detailed herein below, various embodiments present an approach that employs a scanned energetic beam in conjunction with a greyscale resist layer to selectively pattern the greyscale resist layer to match a roughness pattern or surface topography of an underlying substrate. The patterned greyscale photoresist layer may then be used as an etch mask to selectively etch portions of the underlying substrate to reduce topography and reduce TTV.

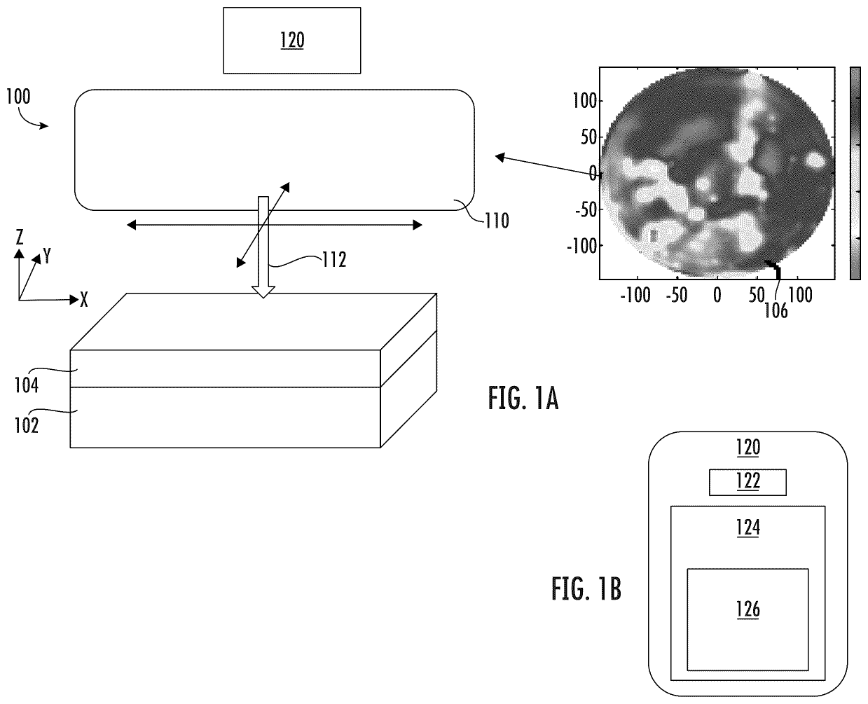

Referring now to FIG. 1A, an exemplary system in accordance with the present disclosure is shown. The lithography system 100 represents a lithography system for processing greyscale photoresist. The lithography system 100 may include an illumination source 110 to generate a scanning beam 112 that is used to illuminate a greyscale photoresist layer 104, disposed on a substrate 102. The lithography system 100 may include a controller 120 that is coupled to receive substrate information, such as a thickness map 106, and may use this information to control the scanning beam 112, so as to pattern the greyscale photoresist layer 104, as disclosed in the embodiments to follow.. As detailed below, the scanning beam 112 may be scannable along the Y-direction and the X-direction (of the Cartesian coordinate system shown) in order to selectively expose the greyscale photoresist layer 104, in order to generate a pattern in the greyscale photoresist layer 104 that facilitates reducing the total thickness variation (TTV) of the underlying substrate, meaning the substrate 102. FIG. 1B provides details of an embodiment of the controller 120, discussed further below

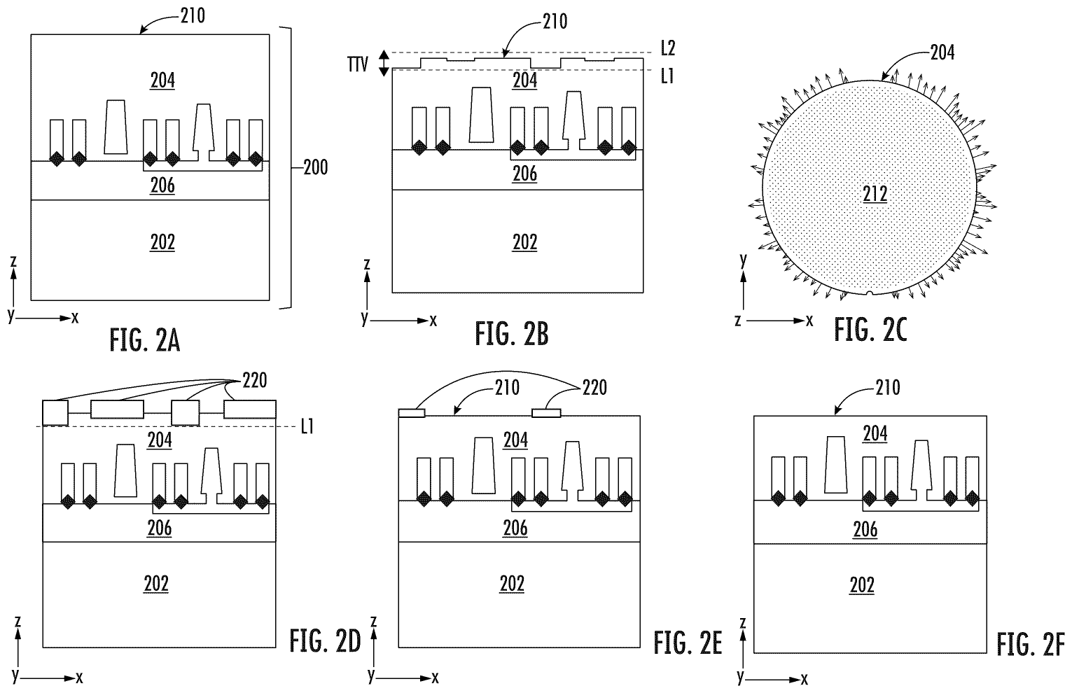

FIGS. 2A-2F depict a semiconductor device at different instances during fabrication, according to embodiments of the disclosure. At FIG. 2A, a device 200 is provided. For purposes of illustration, the device 200 represents a BSPDN device, formed by bonding a carrier substrate 202 together with a device substrate 204. These two substrates may be semiconductor wafers, formed of material such as monocrystalline silicon or a silicon alloy. As in known BSPDN devices, the device substrate 204 may be configured for backside power wiring, which wiring is not present at this stage. Note that in other embodiments, instead of a BSPDN device, a substrate formed of a single semiconductor wafer may be provided. In the specific example of FIG. 2A, the device 200 represents an intermediate stage of fabrication, where wafer thinning of the device substrate 204 is yet to take place. In particular, the surface 210 is to be thinned so as to substantially reduce the overall thickness of the device substrate 204.

At FIG. 2B, the device 200 is shown at a subsequent stage where wafer thinning has been performed. The wafer thinning may be performed, for example, by grinding according to known processes. Note that the initial thickness of the device substrate 204 at FIG. 2A may be several tens of micrometers to hundreds of micrometers, while the thickness of the device substrate 204 after grinding in FIG. 2B may be on the order of 10 micrometers or less, such as 5 micrometers. The surface 210 at this stage may exhibit considerable surface roughness as depicted in FIG. 2B. For example, given an overall thickness of 5 micrometers, the surface 210 may be a rough surface that is defined by a total thickness variation (TTV) of 1 micrometer. Assuming the inner surface of the device substrate 204 is ideally flat, this total thickness variation may be illustrated by a level L1, representing the lowest region on the surface 210, and a level L2, representing the highest region on the surface 210. The differences between these two levels may define the TTV.

After the operation of FIG. 2B, at the instance of FIG. 2C, a thickness map of the device substrate 204 may be obtained. As shown in the top plan view, this thickness map may be a topography map that is arranged as a two-dimensional pixel array, where thickness information is associated with each pixel, and may define a qualitative roughness pattern on the device substrate 204, as well as a value of TTV.

FIG. 2D depicts a subsequent instance where a patterned greyscale photoresist layer 220 is formed on the surface 210 of device substrate 204. The patterned greyscale photoresist layer 220 may be formed by providing a blanket photoresist layer on the surface 210, and then subjecting the blanket photoresist layer to exposure in a greyscale lithography system. The blanket photoresist layer may be formed using a known greyscale photoresist that is sensitive to dose or energy from an illumination source. For example, the greyscale lithography system may use a scanned visible light or ultraviolet beam to perform a direct write process that locally varies the energy deposited into the greyscale photoresist layer as a function of position in the X-Y plane. Note that greyscale photoresists may exhibit a dose range or energy range where thickness of greyscale photoresist after exposure and development varies in a controlled manner with change in energy. Thus, by scanning a beam across the surface of the device substrate 204 in a manner to locally vary the energy deposited into a greyscale photoresist layer, a patterned greyscale photoresist layer 220 may be formed having varying thickness as shown. More particularly, the thickness pattern of the patterned greyscale photoresist layer 220 may be designed to compensate for the pattern of roughness of the surface 210 of device substrate 204, as further detailed below.

At the stage of FIG. 2E, the device 200 has been subjected to an etch process that removes at least a portion of the patterned greyscale photoresist layer 220, as well as select regions of the surface 210. In some non-limiting embodiments, the etch process may be a reactive ion etching process (RIE). In some non-limiting embodiments, the etch process may be non-selective between photoresist and device substrate 204, such that the etch rate of these two materials is approximately the same. Because the patterned greyscale photoresist layer 220 may initially exhibit a variable thickness according to location on the surface 210, including locations of no thickness, the subsequent amount of etching of the surface 210 will vary among different locations, according to the thickness of the patterned greyscale photoresist layer 220 at the different locations. Thus, because the patterned greyscale photoresist layer 220 may be arranged to place relatively thicker resist upon relatively lower height (in the Z-direction) locations on the surface 210, these lower height locations will tend to retain photoresist the longest during etching and will accordingly be etched the least. Moreover, the locations of surface 210 having relatively thinner resist before etching, representing greater height locations, will be etched the most. As such, the overall TTV of the device substrate 204 is reduced after etching using the patterned greyscale photoresist layer 220.

Said differently, the patterned greyscale photoresist layer 220 acts as a greyscale mask for the surface 210, to generate variable etching of the surface 210 according to the pattern of the patterned greyscale photoresist layer 220. Thus, when the pattern of the patterned greyscale photoresist layer 220 is matched to complement the topography pattern of the two dimensional surface map that represents the surface 210 (see FIG. 2C), the etching process will reduce or remove the topography pattern by selectively removing locations of greater thickness, or height.

At the stage of FIG. 2F, any residual portions of the patterned greyscale photoresist layer 220 may be selectively removed, and the surface 210 may be optionally subjected to a final polishing operation, such as a chemical-mechanical polishing (CMP). As such, the surface 210 may be smoother than at FIG. 2B, and the TTV may be reduced.

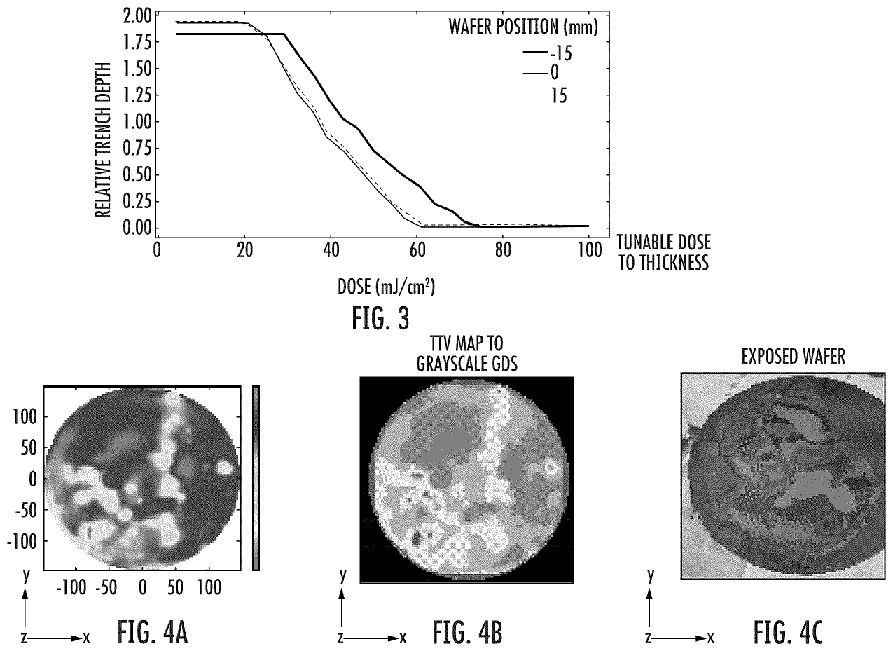

FIG. 3 and FIGS. 4A-4C are presented to further explain the operation of the present embodiments. FIG. 3 is a graph depicting greyscale photoresist etch behavior when subject to a post-exposure developer, as a function of dose energy when exposed to a greyscale lithography system. The Y-axis represents the thickness of a greyscale photoresist layer that is etched after being subjected to a patterning source, such as a UV light source. Thus, the lower values of trench depth represent a greater amount of etching. As shown, at dose levels ranging up to 20 mJ or so, no etching takes place, while at approximately 60-70 mJ and above, the photoresist layer is completely etched. In the intermediate dose range, the greyscale range, over approximately 20 mJ-60 mJ, the etch rate varies linearly with increased dose. Thus, in this wide range of dose, the exact thickness of the photoresist layer after exposure to a patterning source and development can be precisely tuned by setting the dose.

FIG. 4A provides an exemplary thickness map of a semiconductor wafer. In this example, the thickness exhibits an irregular pattern as shown, characterized by a TTV value of 905 nm, just less than one micrometer. Note that the total average thickness of the semiconductor wafer at this point is just 5 micrometers.

FIG. 4B provides an exemplary dose map for a greyscale lithography system, based upon the thickness map of FIG. 4A. According to the present embodiments, a thickness map may be processed to generate a digital file, dose map, or other entity that presents a mapping of dose to be applied to a substrate according to position within a two-dimensional matrix that represents the surface of a substrate. In particular, the dose map of FIG. 4B may present a two-dimensional dose pattern to be implemented by a greyscale lithography system, where the dose pattern matches the thickness pattern of the thickness map of FIG. 4A. Thus, the dose map of FIG. 4B may be based upon the thickness map of FIG. 4A. More particularly, the dose map of FIG. 4B may be designed for implementation using an energetic species that is directed into a greyscale photoresist layer where the post-development thickness is sensitive to dose of the energetic beam, according to a known function, such as the function shown in FIG. 3. Implementation of the dose map may take place by scanning a beam in a variable manner to locally deposit the dose called for at each location of the dose map.

FIG. 4C provides a surface image of a substrate, coated with a greyscale photoresist layer, after being subjected to an energetic species directed to the greyscale photoresist layer according to the dose map of FIG. 4B. Thus, the surface view represents an image of the greyscale photoresist layer, after development, where the visible pattern is indicative of varying thickness of the photoresist layer that results from the photoresist being exposed to the variable dose pattern of FIG. 4B.

According to embodiments of the disclosure, a greyscale lithography operation may be performed by exposing a given substrate having a greyscale photoresist layer deposited thereon to a variable dose that varies at different locations on the substrate. The variable dose is imparted by changing the exposure of the greyscale photoresist layer to an energetic species as a function of location on the substrate. According to various embodiments, the variable dose may be changed over a discrete number of greyscale lithography levels. For example, the different locations on the substrate may be partitioned into a two dimensional pixel array with a pixel size on the order of 10 micrometers, 20 micrometers, or so. In the case of a laser used as a lithography illumination source, the laser intensity may be modulated on a pixel by pixel basis to control the variable dose imparted into the greyscale lithography layer per pixel. In some examples, the intensity or power level of such a laser source may be varied over up to 1024 different settings, corresponding to 1024 different greyscale lithography ‘levels’ that are available to exposed any give pixel on the substrate.

After exposure, the exposed and developed greyscale photoresist layer and portions of the underlying substrate are subject to etching.

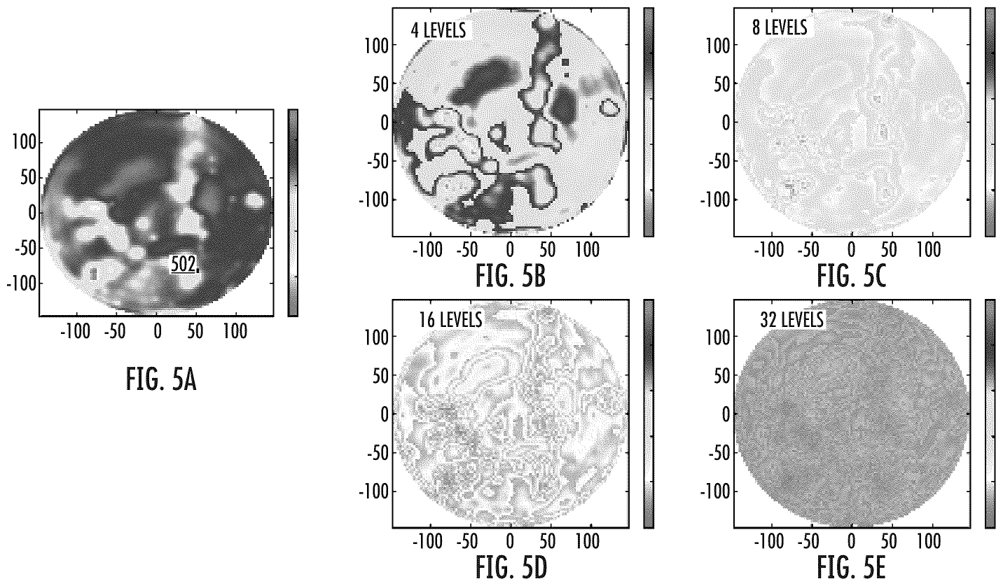

FIGS. 5A-5E provide exemplary thickness maps of a substrate 502, after processing using various greyscale lithography levels, according to some embodiments of the disclosure. The thickness maps are simulations based upon the assumption that photoresist thickness and etch selectivity are tuned for a given amount of TTV. In this example, FIG. 5A may represent the situation before any greyscale lithography operation takes place, for example, immediately after a grinding operation has been performed. As noted previously, a substrate, such as substrate 502 may be characterized by an average thickness of say, 5 micrometers, after grinding. Thus, the substrate 502 exhibits a TTV of 905 nm as shown in FIG. 5A, before greyscale lithographic processing.

At FIG. 5B, the thickness map presents an image of the substrate 502, after processing using four greyscale lithography levels (or simply “levels,” hereinafter). At this stage the TTV is reduced in half to 452 nm. At FIG. 5C, after processing using 8 levels, the TTV is reduced in half again to 226, while at FIG. 5D, after processing using 16 levels TTV reduces to 113 nm, while at 32 levels, shown in FIG. 5E, TTV is 56 nm. Thus, for each doubling of the number of greyscale lithography levels, TTV reduces by half.

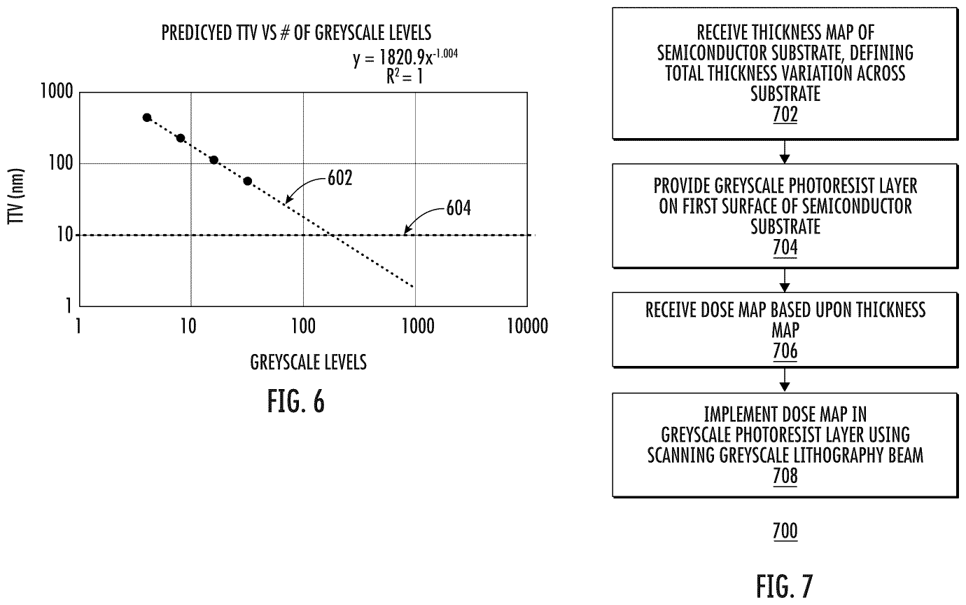

Following the example of FIGS. 5A-5E, FIG. 6 is a graph illustrating the theoretical change in TTV as a function of the number of greyscale lithography levels used to expose and pattern a greyscale photoresist layer, followed by etching of the patterned greyscale photoresist layer and underlying substrate, as discussed above. For the purposes of illustration, the curve 602 extends from four levels to 1000 levels. Note that present day lithography tools are readily capable to generate 1024 levels. FIG. 6 also illustrates a target TTV level 604, in this case, 10 nm. Based upon the curve 602, exposing a greyscale photoresist layer to approximately 200 greyscale lithography levels or so may be sufficient to reach this target of 10 nm, readily within the capabilities of a known greyscale lithography system.

To explain further the operations related generating a variable dose patterning of a greyscale photoresist layer, FIG. 1B shows further details of the controller 120. In various embodiments, the controller 120 be form a part of the system 100, while in some embodiments, the controller 120 may be coupled to the lithography system 100. In this embodiment, the controller 120 may include a processor 122, such as a known type of microprocessor, dedicated processor chip, general purpose processor chip, or similar device. The controller 120 may further include a memory or memory unit 124, coupled to the processor 122, where the memory unit 124 contains a variable dose routine 126. The variable dose routine 126 may be operative on the processor 122 to manage a lithography process, including operations as detailed in the process flows to follow. For example, the variable dose routine 126 may be operative on the processor to manage a lithography process using a scanning beam 112, in order to impart variable dose into the greyscale photoresist layer 104, and thus generate a patterned photoresist layer, as discussed above. In one embodiment, the controller 120 may be adapted to store a thickness map for a substrate to be processed, such as in the memory unit 124. In some embodiments, the processor 122 may operate to generate a dose map based upon a thickness map that is stored in the memory unit 124.

The memory unit 124 may comprise an article of manufacture. In one embodiment, the memory unit 124 may comprise any non-transitory computer readable medium or machine readable medium, such as an optical, magnetic or semiconductor storage. The storage medium may store various types of computer executable instructions to implement one or more of logic flows described herein. Examples of a computer readable or machine-readable storage medium may include any tangible media capable of storing electronic data, including volatile memory or non-volatile memory, removable or non-removable memory, erasable or non-erasable memory, writeable or re-writeable memory, and so forth. Examples of computer executable instructions may include any suitable type of code, such as source code, compiled code, interpreted code, executable code, static code, dynamic code, object-oriented code, visual code, and the like. The embodiments are not limited in this context.

FIG. 7 illustrates an exemplary process flow 700. At block 702, a thickness map of a semiconductor substrate is received. The thickness map present the thickness of the substrate, as a function of position in a two-dimensional array across a surface of the semiconductor substrate. As such, the thickness map may constitute a two-dimensional array of pixels, representing substrate thickness information at each pixel. In various non-limiting embodiments, the thickness map may define a total thickness variation (TTV) across the semiconductor substrate. In various embodiments, the pixel size may be suitably constructed, for example, may be less than 20 micrometers, or less than 10 micrometers. According to various embodiments, the first surface may be a surface that has been subjected to grinding, and presents a relatively rougher surface. In particular embodiments, the semiconductor substrate may be part of a bonded device where just the first surface is exposed. In one embodiment, the semiconductor substrate may be device substrate that is bonded to a carrier substrate in a BDPDN device.

At block 704, a greyscale photoresist layer is provided on a first surface of the semiconductor substrate. According to various embodiments, the greyscale photoresist layer is provided as a uniform-thickness, blanket layer on the first surface.

At block 706, a dose map is received, based upon the thickness map. The dose map may be received in a greyscale photoresist lithography tool in some examples. The dose map may be a two-dimensional map presenting variable dose of an energetic species to be imparted into the greyscale photoresist layer as a function of location across the first surface of the semiconductor substrate. The variable dose may be presented in a pixel array having a pixel size comparable to the pixel size of the thickness map, according to some embodiments. The dose map may be calculated to generate a variable thickness in the greyscale photoresist layer as a function of location on the first surface, when the greyscale photoresist layer is exposed to the energetic species and developed. The variable thickness of the greyscale photoresist layer may be calculated to compensate for the variable thickness of the semiconductor substrate as a function of location. Thus, a pixel representing a location where the thickness of the semiconductor substrate is relatively larger may be targeted with a relatively larger dose, while a pixel representing a region where the thickness of the semiconductor substrate is relatively lesser may be targeted with a relatively smaller dose.

At block 708, the dose map is implemented in the greyscale photoresist layer using a scanning beam in a greyscale photoresist lithography system (tool). The scanning beam may perform a direct write process to impart a variable dose of energetic species into the greyscale photoresist layer according to the dose map. The energetic species may be photons such as UV radiation in some instances. Alternatively, the greyscale photoresist lithography tool may implement the dose map using a greyscale mask that is patterned to provide variable dose when an energetic species is directed through the greyscale photoresist mask.

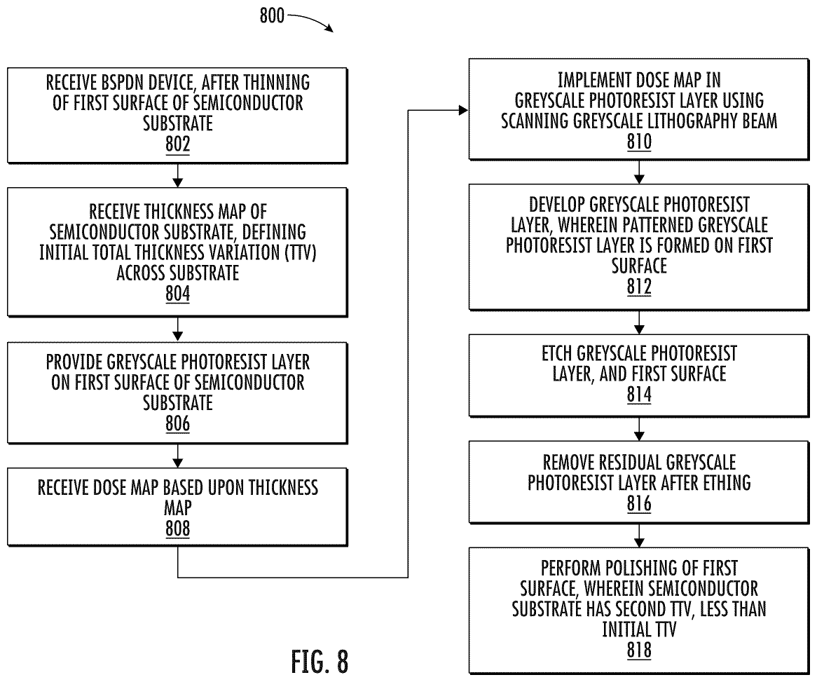

FIG. 8 illustrates another exemplary process flow 800. At block 802, a BSPDN device is received, after thinning of a first surface of semiconductor substrate that forms part of the PSPDN device. In particular, the semiconductor substrate may be a device substrate, having a second surface that is bonded to a carrier substrate.

At block 804, a thickness map of the semiconductor substrate is received, defining an initial total thickness variation (TTV) across the semiconductor substrate. The dose map may be received in a greyscale photoresist lithography tool in some examples. The dose map may be a two-dimensional map presenting variable dose of an energetic species as a function of position across the first surface of the semiconductor substrate.

At block 806 a greyscale photoresist layer is provided on the first surface of the semiconductor substrate.

At block 808, a dose map dose map is received based upon the thickness map.

At block 810, the dose map is implemented in the greyscale photoresist layer using a scanning beam to direct-write a pattern of variable dose into the greyscale photoresist layer.

At block 812, the greyscale photoresist layer is developed, wherein a patterned greyscale photoresist layer is formed on the first surface, such that the patterned greyscale photoresist layer forms a two dimensional array of variable thickness at different locations across the first surface of the semiconductor substrate.

At block 814, the greyscale photoresist layer and the first surface of the semiconductor substrate are subjected to an etch process. In some embodiments, the etch process may be a reactive ion etching process. In some embodiments, the etch process may be non-selective, where the etch rate of the semiconductor substrate is the same as the etch rate of the greyscale photoresist layer.

At block 816, a residual greyscale photoresist layer is removed from the first surface after the etch process. The removal of the greyscale photoresist layer may be performed in a selective manner so as not to etch the first surface of the semiconductor substrate.

At block 818, a polishing operation is performed on the first surface, wherein, after the polishing operation, the semiconductor substrate has a second TTV, less than the initial TTV. In some examples, the polishing operation may be a chemical-mechanical polishing operation.

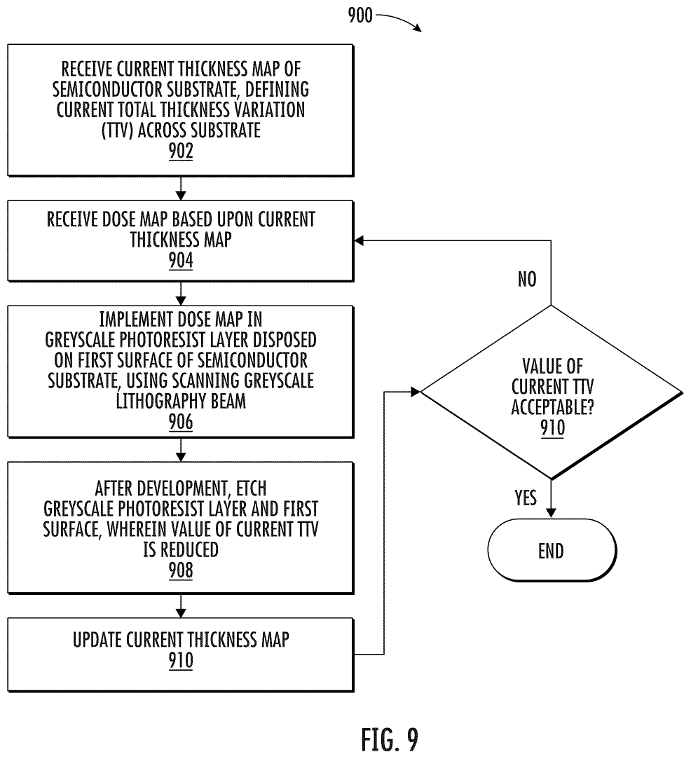

FIG. 9 illustrates a further exemplary process flow 900. At block 902, a current thickness map of a semiconductor substrate is received, defining a current total thickness variation (TTV) across the semiconductor substrate.

At block 904, a dose map is received, based upon the current thickness map. The dose map may be received in a greyscale photoresist lithography tool in some examples. The dose map may be a two-dimensional map presenting variable dose of an energetic species as a function of position across a first surface of the semiconductor substrate.

At block 906, the dose map is implemented in a greyscale photoresist layer disposed on the first surface of the semiconductor substrate, using a scanning greyscale lithography beam.

At block 908, after development of the greyscale photoresist layer, the greyscale photoresist layer and first surface of the semiconductor substrate are etched, wherein a value of the current TTV of the semiconductor substrate is reduced.

At block 910, the current thickness map is updated after the etching, where the current thickness map defines a current TTV.

The flow then proceeds to decision block 912, where a determination is made as to whether the value of the current TTV is acceptable. If so, the process ends. If not, the flow returns to block 904.

Advantages provided by the present embodiments are multifold. As a first advantage, the present approach, employing greyscale lithography matched to the pattern of thickness variation on a substrate, provides a simpler and more cost effective approach to reducing TTV as compared to schemes based upon complicated etch processing. As another advantage, the present approach enables technologies that require thin substrates having ultra-uniform thickness, such as BSPDN devices, where device substrates are to be thinned to levels of 5 micrometers, and TTV is to be kept at levels of 10 nm or less.

The present disclosure is not to be limited in scope by the specific embodiments described herein. Indeed, other various embodiments and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose, yet those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method of topography correction in a substrate, comprising:
receiving a thickness map of a substrate, the thickness map defining a total thickness variation across the substrate;
providing a greyscale photoresist layer on a first surface of the substrate; and
performing a greyscale lithography operation on the greyscale photoresist layer, based upon the thickness map, wherein the greyscale lithography operation is to reduce the total thickness variation.

2. The method of claim 1,
wherein the substrate is subject to a thinning before the thickness map is generated,
wherein the thinning produces a rough surface in the substrate, and
wherein the thickness map is a thickness map of the rough surface.

3. The method of claim 1, wherein the performing the greyscale lithography operation comprises:
exposing the greyscale photoresist layer to a variable dose of an energetic species, as a function of location across the first surface.

4. The method of claim 3, wherein the performing the greyscale lithography operation further comprises:
developing the greyscale photoresist layer; and
performing a blanket etch process to etch the greyscale photoresist layer and at least a portion of the first surface of the substrate,
wherein before the greyscale operation, the substrate exhibits a first total thickness variation, and
wherein after the greyscale lithography operation, the substrate exhibits a second total thickness variation, less than the first total thickness variation.

5. The method of claim 4, wherein the substrate comprises monocrystalline silicon, wherein the blanket etch process etches the greyscale photoresist layer at a first rate, R1 and etches the substrate at a second rate, R2, wherein R1/R2 is between 0.9 and 1.1.

6. The method of claim 3, wherein the thickness map comprises a two dimensional surface map providing a total thickness of the substrate as a function of location along the first surface.

7. The method of claim 6, wherein the performing the greyscale lithography operation comprises:
generating a dose map from the two dimensional surface map;
and applying the variable dose to the greyscale photoresist layer.

8. The method of claim 7, wherein the dose map comprises a two-dimensional pixel array, wherein a pixel size of the two-dimensional pixel array is less than 10 mm.

9. The method of claim 7, wherein the performing the greyscale lithography operation comprises exposing the greyscale photoresist layer to a plurality of different greyscale lithography levels according to different locations on the substrate.

10. A lithography system, comprising:
an illumination source, to generate a scanning beam; and
a controller, coupled to the scanning beam, the controller comprising:
a processor; and
a memory unit coupled to the processor, wherein the processor to control the lithography system to:
receive a thickness map of a substrate, the thickness map defining a total thickness variation across the substrate; and
control the scanning beam to perform a greyscale lithography operation on a greyscale photoresist layer on the substrate, based upon the thickness map.

11. The lithography system of claim 10, the processor operative to control the scanning beam to impart a variable dose of energetic species into the greyscale photoresist layer, as a function of location across a first surface of the substrate.

12. The lithography system of claim 11, wherein the thickness map comprises a two dimensional surface map providing a total thickness of the substrate as a function of location along the first surface.

13. The lithography system of claim 12, wherein the processor operative to:
generate a dose map from the two dimensional surface map; and
control the scanning beam to apply the variable dose to the greyscale photoresist layer.

14. The lithography system of claim 10,
wherein the substrate is subject to a thinning before the thickness map is generated,
wherein the thinning produces a rough surface in the substrate, and
wherein the thickness map is a thickness map of the rough surface.

15. The lithography system of claim 12, wherein the processor is operative to control the lithography system to:
expose the greyscale photoresist layer to a plurality of different greyscale lithography levels according to different locations on the substrate.

16. A controller for a lithography system, comprising:
a processor; and
a memory unit coupled to the processor, wherein the processor to control a lithography system to:
receive a thickness map of a substrate; and
control a scanning beam to perform a greyscale lithography operation on a greyscale photoresist layer on the substrate, based upon the thickness map.

17. The controller of claim 16, the processor operative to control the scanning beam to impart a variable dose of energetic species into the greyscale photoresist layer, as a function of location across a first surface of the substrate.

18. The controller of claim 17, wherein the thickness map comprises a two dimensional surface map providing a total thickness of the substrate as a function of location along the first surface.

19. The controller of claim 18, wherein the processor is operative to:
generate a dose map from the two dimensional surface map; and
control the scanning beam to apply the variable dose to the greyscale photoresist layer.

20. The controller of claim 16,
wherein the substrate is subject to a thinning before the thickness map is generated,
wherein the thinning produces a rough surface in the substrate, and
wherein the thickness map is a thickness map of the rough surface.
